(19) United States
(12) Patent Application Publication
(10) Pub. No.: US 2008/0235440 A1
(43) Pub. Date: Sep. 25, 2008

(54) Memory device

(76) Inventor: Trung V. Le, White Bear Township, MN (US)

Correspondence Address: Eric D. Levinson;Imation Corp., Legal Affairs, P.O. Box 64898, St. Paul, MN, 55164-0898, US

(21) Appl. No.: 11/726,714

(22) Filed: Mar. 22, 2007

(51) Int. Cl. G11C 5/06

(52) U.S. Cl. 711/103

(57) ABSTRACT

A memory device includes a housing, a memory within the housing, and a first electrical interface accessible on a top surface of the housing and a second electrical interface accessible on a bottom surface of the housing. As such, at least one of the first electrical interface and the second electrical interface is configured to establish electrical connection of the memory device with an electrical interface of another memory device when the memory device and the another memory device are in a stacked configuration.

### FIELD OF INVENTION

The present invention relates generally to memory devices.

### BACKGROUND

A wide variety of memory devices having different capacities, access speeds, formats, interfaces, and connectors are available for storing data. Such devices support various memory forms including, for example, electrically erasable programmable memory (FLASH), electrically erasable programmable read-only memory (EEPROM), non-volatile random access memory (NVRAM), micro hard-disk drives, and other non-volatile or volatile memory types, such as synchronous dynamic random access memory (SDRAM).

Existing memory devices typically include a specialized connector for coupling to a computing device. For example, a memory device connector may couple to a host computer via a host computer interface, such as a personal computer memory card international association (PCMCIA) interface including a 16 bit standard PC Card interface and a 32 bit standard CardBus interface, a Universal Serial Bus (USB) interface, a Universal Serial Bus 2 (USB2) interface, an IEEE 1394 FireWire interface, a Small Computer System Interface (SCSI) interface, an Advance Technology Attachment (ATA) interface, a serial ATA interface, an Integrated Device Electronic (IDE) interface, an Enhanced Integrated Device Electronic (EIDE) interface, a Peripheral Component Interconnect (PCI) interface, a PCI Express interface, a conventional serial or parallel interface, or another interface that facilitates communication with a host computer.

Existing memory devices may include one or more memory storage units that define a fixed storage capacity of the device, which generally cannot be expanded. In addition, with such devices, there will always be some storage capacity limit of the devices based on a specific physical format of a respective device. As such, if a higher storage capacity is needed, a user may need to purchase a new memory device with a larger, fixed storage capacity. For example, many flash memory drives currently have a capacity limit of approximately 2 gigabytes (GB) because the small physical format of the flash memory drive allows for only one flash memory chip. Thus, if a user desires a higher capacity flash drive, the user would typically have to purchase a larger, bulky drive, which typically sells at a more expensive price.

For these and other reasons, a need exists for the present invention.

### SUMMARY

One aspect of the present invention provides a memory device including a housing, a memory within the housing, and a first electrical interface accessible on a top surface of the housing and a second electrical interface accessible on a bottom surface of the housing. As such, at least one of the first electrical interface and the second electrical interface is configured to establish electrical connection of the memory device with an electrical interface of another memory device when the memory device and the another memory device are in a stacked configuration.

Another aspect of the present invention provides a memory device including a housing, a memory within the housing, and means provided on a top surface of the housing and a bottom surface of the housing for establishing electrical connection between the memory device and another memory device when the memory device and the another memory device are in a stacked configuration.

Another aspect of the present invention provides a memory system including a first memory device including a first housing, a first memory within the first housing, and a first electrical interface provided on one of a top surface and a bottom surface of the first housing; and a second memory device including a second housing, a second memory within the second housing, and a second electrical interface provided on one of a top surface and a bottom surface of the second housing opposite the one of the top surface and the bottom surface of the first housing. As such, the first electrical interface of the first memory device and the second electrical interface of the second memory device are configured to establish electrical connection between the first memory device and the second memory device when the first memory device and the second memory device are in a stacked configuration.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 is a schematic diagram illustrating one embodiment of a memory device.

FIG. 2 is a schematic perspective view illustrating one embodiment of a memory device.

FIG. 3A is a top view of one embodiment of a memory device.

FIG. 3B is a bottom view of one embodiment of a memory device.

FIG. 3C is a schematic diagram illustrating one embodiment of electrical contacts of one embodiment of an electrical interface of a memory device.

FIG. 4A is a top view of another embodiment of a memory device.

FIG. 4B is a bottom view of another embodiment of a memory device.

FIG. 4C is a schematic diagram illustrating one embodiment of electrical contacts of another embodiment of an electrical interface of a memory device.

FIG. 5 is a schematic diagram illustrating one embodiment of connection between memory devices.

FIG. 6 is a schematic diagram illustrating one embodiment of a stacked configuration of memory devices.

FIG. 7 is a schematic diagram illustrating one embodiment of operative communication of memory devices with a host device.

FIG. 8 is a schematic diagram illustrating another embodiment of a stacked configuration of memory devices.

FIG. 9 is a schematic diagram illustrating another embodiment of operative communication of memory devices with a host device.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” etc., is used with reference to the orientation of the Figure(s) being described. Because components of embodiments described herein can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

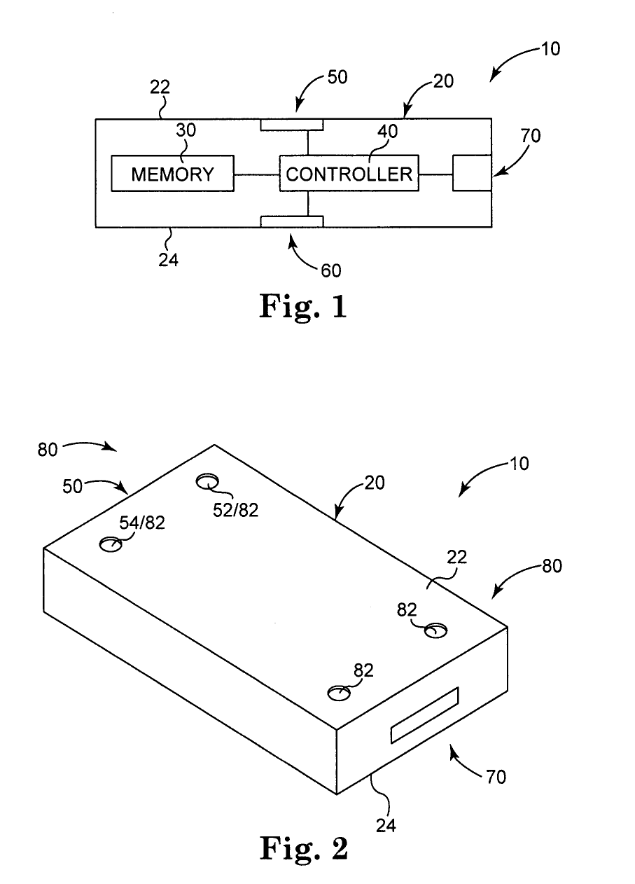

FIG. 1 illustrates one embodiment of a memory device 10. Memory device 10 includes a housing 20, a memory 30, a controller 40, electrical interfaces 50 and 60, and a host interface 70. As described below, electrical interfaces 50 and 60 provide electrical connection of memory device 10 with another memory device or a tray for memory device 10, and host interface 70 provides electrical connection of memory device 10 with a host device.

In one embodiment, one or more other memory devices similar to memory device 10 may be stacked adjacent memory device 10 and electrically coupled to memory device 10 through either electrical interface 50 or electrical interface 60, as described below. In this way, memory device 10 and the additional memory devices may be coupled to a host device via one host interface. As such, the amount of memory available to the host device can be increased while maintaining a small form factor for each of the memory devices. In addition, the plurality of memory devices can be presented to the host device as a single virtual memory device.

By providing electrical connection between and among memory devices 10 and a host device, electrical interfaces 50 and 60 and host interface 70 facilitate operative communication between and among memory devices 10 and a host device. In one embodiment, as described below, electrical interfaces 50 and 60 facilitate communication of data, ground, and/or power signals between adjacent memory devices when one or more memory devices 10 are arranged in a stacked configuration.

In one embodiment, each memory device is designed with electronics to propagate and communicate data, ground, and/or power signals to an adjacent memory device. In addition, the memory devices include the ability to recognize the communication from an adjacent memory device and determine whether it is the memory device being interrogated or whether it needs to pass the communication on to another memory device within the stack.

In one embodiment, housing 20 is generally rectangular in shape and includes a top surface 22 representing a first major surface of memory device 10, and a bottom surface 24 representing a second major surface of memory device 10 opposite top surface 22.

In one embodiment, memory 30 and controller 40 are positioned within housing 20, and electrical interfaces 50 and 60 and host interface 70 are accessible on housing 20. In one embodiment, for example, electrical interface 50 is accessible on top surface 22 of housing 20, and electrical interface 60 is accessible on bottom surface 24 of housing 20. In one embodiment, memory 30 is operatively coupled with controller 40, and electrical interfaces 50 and 60 and host interface 70 are operatively coupled with controller 40 such that memory 30 is operatively coupled with electrical interfaces 50 and 60 and host interface 70 via controller 40.

Memory 30 make take the form of or include one or more of a variety of storage medium such as a disk-shaped magnetic storage medium, a solid-state storage medium, an optical storage medium, a magneto-optical storage medium, and a holographic storage medium. Memory 30 may include, for example, a non-volatile memory such as an erasable programmable read-only memory (EPROM), an electrically erasable programmable read-only memory (EEPROM), an electrically erasable programmable memory (FLASH), a non-volatile random access memory (NVRAM), and other non-volatile or volatile memory types, such as a synchronous dynamic random access memory (SDRAM). In one embodiment, memory 30 is a random access storage medium. In one exemplary embodiment, memory 30 is a hard-disk drive.

In one embodiment, electrical interfaces 50 and 60 of memory device 10 facilitate operative communication of memory device 10 with another memory device similar to memory device 10. For example, with electrical interfaces 50 and 60 provided on top surface 22 and bottom surface 24, memory device 10 and one or more other memory devices similar to memory device 10 may be arranged in a stacked configuration with the other memory devices provided above and/or below memory device 10. As such, in one embodiment, as described below, operative communication between one or more other memory devices and a host device is provided via host interface 70 through memory device 10. Accordingly, multiple memory devices may be operatively coupled with a host device via one host interface.

In one embodiment, host interface 70 is operatively coupled with controller 40, and controller 40 is operatively coupled with memory 30. As such, host interface 70 is operatively coupled with memory 30 via controller 40. Thus, in one embodiment, access to memory 30 of memory device 10 by a host device is provided via host interface 70 through controller 40.

In one embodiment, host interface 70 conforms to a host connection standard. The host connection standard may comprise, for example, a personal computer memory card international association (PCMCIA) standard including a 16 bit standard PC Card and a 32 bit standard CardBus, a Universal Serial Bus (USB) standard, a Universal Serial Bus 2 (USB2) standard, a future generation USB standard, an IEEE 1394 FireWire standard, a Small Computer System Interface (SCSI) standard, an Advance Technology Attachment (ATA) standard, a serial ATA standard, an Integrated Device Electronic (IDE) standard, an Enhanced Integrated Device Electronic (EIDE) standard, a Peripheral Component Interconnect (PCI) standard, a PCI Express standard, a conventional serial or parallel standard, a wireless connection standard such as wireless USB, ZigBee, or Wi-Fi, or any other standard that facilitates operative communication with a host device, as described below.

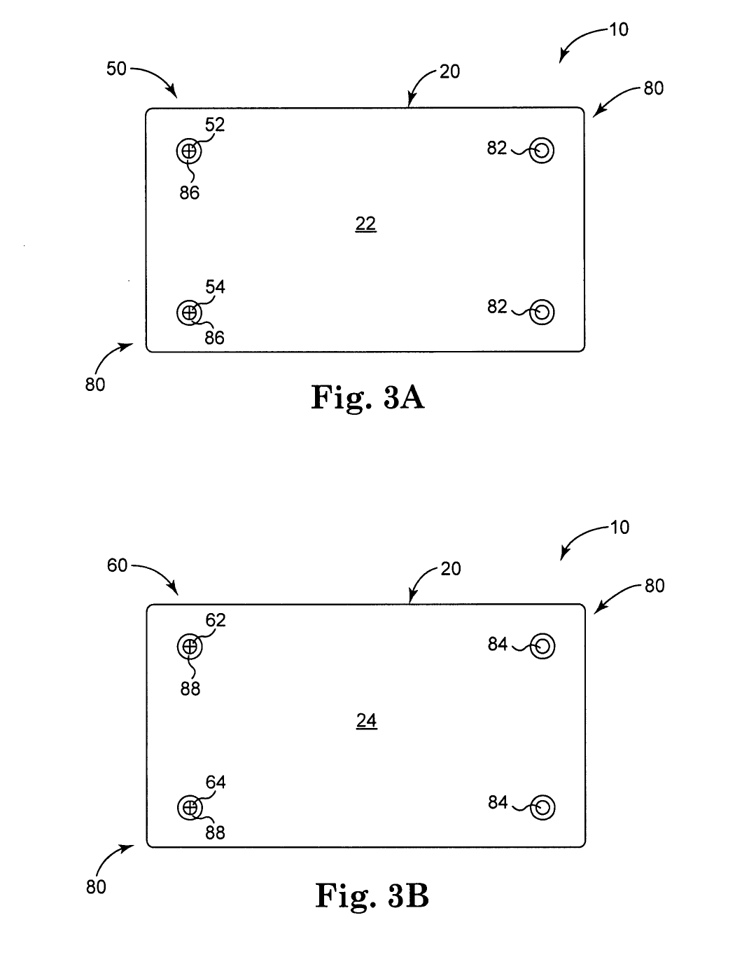

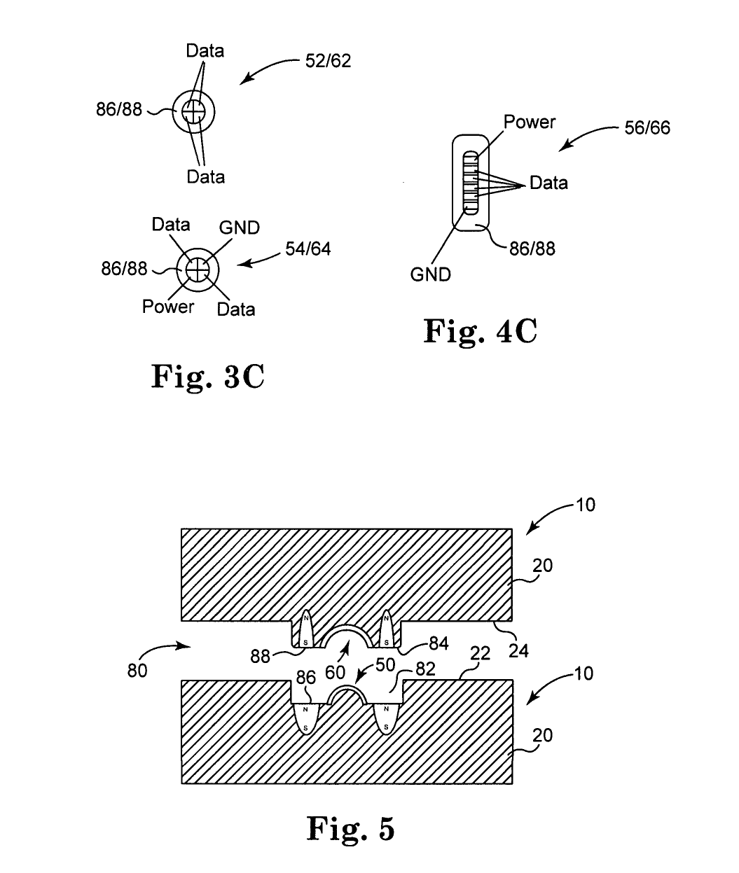

FIGS. 2, 3A, and 3B illustrate one embodiment of memory device 10, including one embodiment of electrical interfaces 50 and 60, and one embodiment of host interface 70. In one embodiment, electrical interfaces 50 and 60 include complementary electrical interfaces provided on top surface 22 and bottom surface 24, respectively, of housing 20. As such, electrical interfaces 50 and 60 facilitate operative communication of memory device 10 with another device similar to memory 10. More specifically, electrical interfaces 50 and 60 enable one or more memory devices 10 to communicate with each other and/or communicate with a host device when arranged in a stacked configuration as described below.

In one embodiment, a position and/or arrangement of electrical interface 50 as provided on top surface 22 of housing 20 corresponds to a position and/or arrangement of electrical interface 60 as provided on bottom surface 24 of housing 20. As such, electrical interface 50 on top surface 22 of memory device is configured to receive and establish electrical connection with electrical interface 60 provided on a bottom surface of another memory device similar to memory device 10, and electrical interface 60 on bottom surface 24 of memory device 10 is configured to mate with and establish electrical connection with electrical interface 50 provided on a top surface of another memory device similar to memory device 10.

In one exemplary embodiment, as illustrated in FIGS. 2, 3A, 3B, and 3C, electrical interface 50 includes a pair of spaced electrical contacts 52 and 54 provided on top surface 22 of housing 20, and electrical interface 60 includes a pair of spaced electrical contacts 62 and 64 provided on bottom surface 24 of housing 20. In one embodiment, a size and position of electrical contacts 52 and 54 is complementary to a size and position of electrical contacts 62 and 64 such that respective electrical contacts 52 and 54, and 62 and 64 establish electrical connection when memory device 10 and another memory device similar to memory device 10 are arranged in a stacked configuration.

As illustrated in the embodiment of FIG. 3C, electrical contacts 52 and 54 of electrical interface 50 and electrical contacts 62 and 64 of electrical interface 60 include individual contacts for data, ground, and power signals. For example, electrical contacts 52 and 62 each include individual contacts for data signals, and electrical contacts 54 and 64 each include individual contacts for data, ground (GND), and power signals.

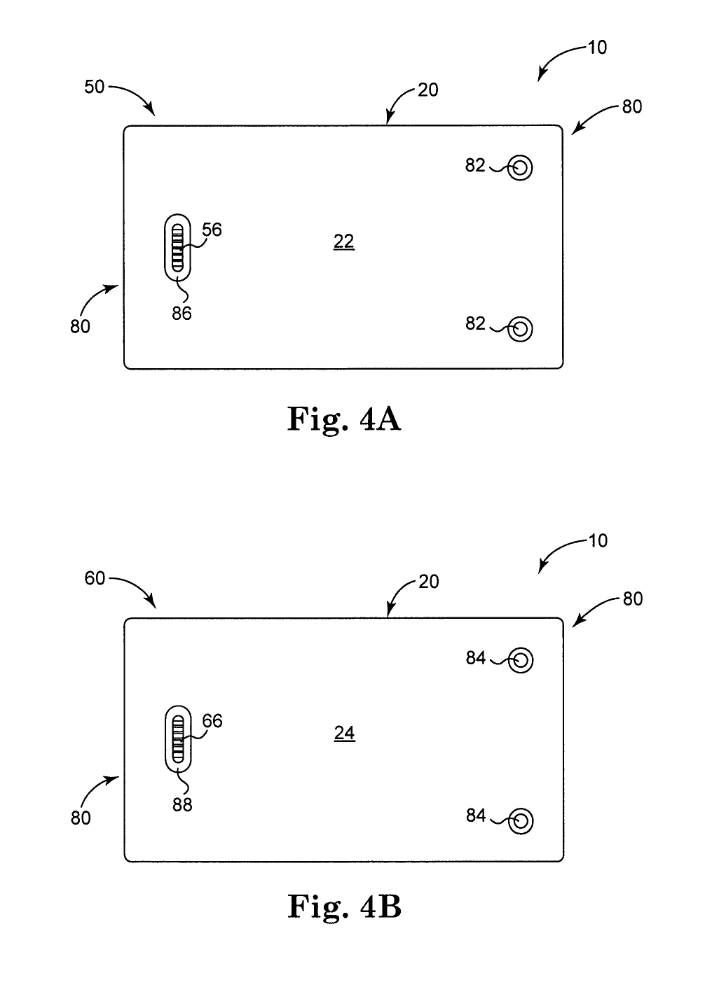

In another exemplary embodiment, as illustrated in FIGS. 4A, 4B, and 4C, electrical interface 50 includes an electrical contact 56 provided on top surface 22 of housing 20, and electrical interface 60 includes an electrical contact 66 provided on bottom surface 24 of housing 20. In one embodiment, a size and position of electrical contact 56 is complementary to a size and position of electrical contact 66 such that electrical contacts 56 and 66 establish electrical connection when memory device 10 and another memory device similar to memory device 10 are arranged in a stacked configuration.

As illustrated in the embodiment of FIG. 4C, electrical contact 56 of electrical interface 50 and electrical contact 66 of electrical interface 60 each include individual contacts for data, ground (GND), and power signals.

Although electrical interfaces 50 and 60 are illustrated and described as being a pair of spaced electrical contacts 52 and 54, and 62 and 64, and an electrical contact 56 and 66, respectively, is it within the scope of the present invention for electrical interfaces 50 and 60 to be of other shapes and/or configuration. In addition, the number of electrical contacts for electrical interfaces 50 and 60 may vary. Furthermore, electrical contacts of electrical interfaces 50 and 60 may include pin-type connectors, pad-type connectors, and/or other types of electrical connectors.

In one embodiment, as illustrated in FIGS. 2-5, memory device 10 includes a stacking feature 80. Stacking feature 80 facilitates positioning of and maintaining a stacked configuration of memory device 10 with another memory device similar to memory device 10. More specifically, stacking feature 80 enables one or more memory devices to be stacked on top of each other in a convenient and stable matter. Furthermore, as described below, stacking feature 80 facilitates mating connection between electrical interfaces 50 and 60 of stacked, adjacent memory devices 10.

In one embodiment, stacking feature 80 includes complementary features provided on top surface 22 and bottom surface 24 of housing 20. In one embodiment, a position or arrangement of features provided on top surface 22 corresponds to a position or arrangement of features provided on bottom surface 24. As such, features provided on top surface 22 of memory device 10 are configured to mate with features provided on a bottom surface of another memory device similar to memory device 10, and features provided on bottom surface 24 of memory device 10 are configured to mate with features provided on a top surface of another memory device similar to memory device 10.

In one embodiment, stacking feature 80 of memory device 10 includes electrical interfaces 50 and 60 as provided on top surface 22 and bottom surface 24 of housing 20. As such, electrical interfaces 50 and 60 as provided on top surface 22 and bottom surface 24, respectively, of memory device 10 perform a dual role of facilitating electrical connection of memory device 10 with another memory device similar to memory device 10, and facilitating positioning of and maintaining a stacked configuration of memory device 10 with another memory device similar to memory device 10. Thus, in one embodiment, stacking feature 80 is formed, in part, by electrical interfaces 50 and 60.

In one exemplary embodiment, as illustrated in FIGS. 2-5, stacking feature 80 includes complementary recesses 82 and projections 84 provided on top surface 22 and bottom surface 24, respectively, of housing 20. In addition, in the embodiment where stacking feature 80 includes electrical interfaces 50 and 60, electrical interfaces 50 and 60 are formed as complementary recesses 82 and projections 84. Although recesses 82 and projections 84 are illustrated as being circular in shape, it is within the scope of the present invention for recesses 82 and/or projections 84 to be of different shapes and/or sizes.

In one embodiment, as illustrated in FIGS. 3A-5, stacking feature 80 includes magnets of opposite polarity provided on top surface 22 and bottom surface 24 of housing 20. In one embodiment, for example, magnets 86 oriented with a first polarization are accessible on top surface 22 of housing 20, and magnets 88 oriented with a second polarization opposite the first polarization are accessible on bottom surface 24 of housing 20.

In one exemplary embodiment, magnets 86 and 88 are provided adjacent electrical interfaces 50 and 60. For example, magnets 86 and 88 are provided adjacent electrical contacts 52 and 54 of electrical interface 50 and electrical contacts 62 and 64 of electrical interface 60, respectively, and adjacent electrical contact 56 of electrical interface 50 and electrical contact 66 of electrical interface 60, respectively. As such, magnets 86 and 88 facilitate a self-aligning connection between electrical interfaces 50 and 60 when memory device 10 and another memory device similar to memory device 10 are arranged in a stacked configuration.

FIGS. 6-9 illustrate embodiments of a memory system 100 including a stacked configuration of multiple memory devices 10. As embodiments of memory device 10, memory devices 101, 102, 103, and/or 104 are arranged in a stacked configuration such that adjacent memory devices are electrically coupled via electrical interfaces 50 and 60, as described above. In one embodiment, memory device 101 facilitates communication of memory devices 101, 102, 103, and/or 104 with a host device 106. Host device 106 may include a host computer 107 in the form of a laptop computer, a desk top computer, a hand held computer, a personal PDA, a cell phone, or any device capable of communicating with the memory system.

In one embodiment, with memory devices 102, 103, and/or 104 operatively coupled with memory device 101, controller 40 (FIG. 1) of memory device 101 acts as a master controller while corresponding controllers of memory devices 102, 103, and/or 104 act as servant or slave controllers. Accordingly, in one embodiment, controller 40 of memory device 101 provides read/write data access to memory 30 (FIG. 1) of memory device 101, as well as read/write data access to respective memory of memory devices 102, 103, and/or 104. In addition, in one embodiment, controller 40 of memory device 101 also provides power to memory devices 102, 103, and/or 104.

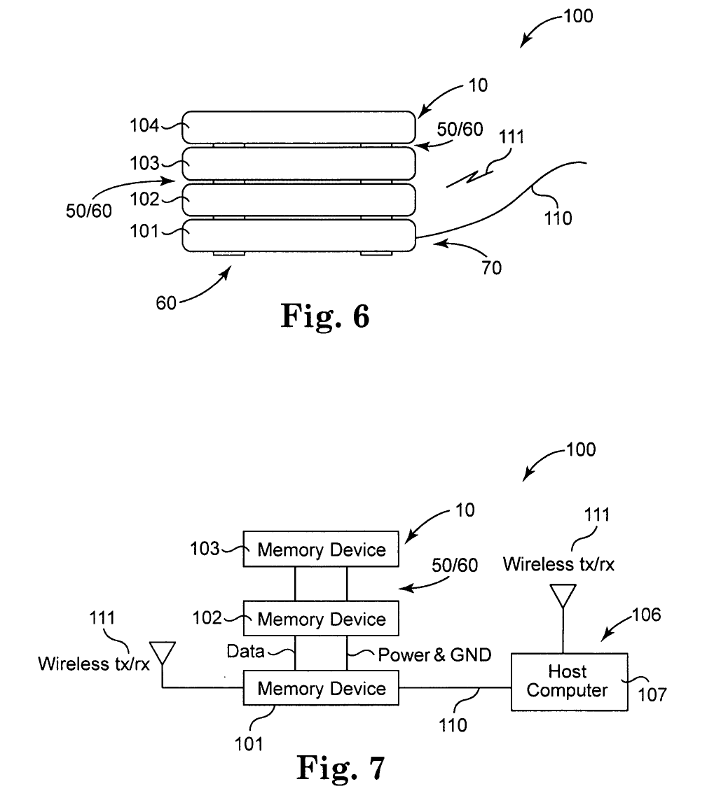

As illustrated in the embodiments of FIGS. 6 and 7, memory device 101 facilitates communication of memory devices 101, 102, 103, and/or 104 with host device 106 via host interface 70. As such, communication between memory devices 101, 102, 103, and/or 104 and host device 106 is provided via host interface 70 through memory device 101. In this way, memory device 101 acts as a gateway for the additional memory devices to communicate with host device 106. In one embodiment, communication between memory device 101 and host device 106 includes a wired connection 110, and in another embodiment, communication between memory device 101 and host device 106 includes a wireless connection 111.

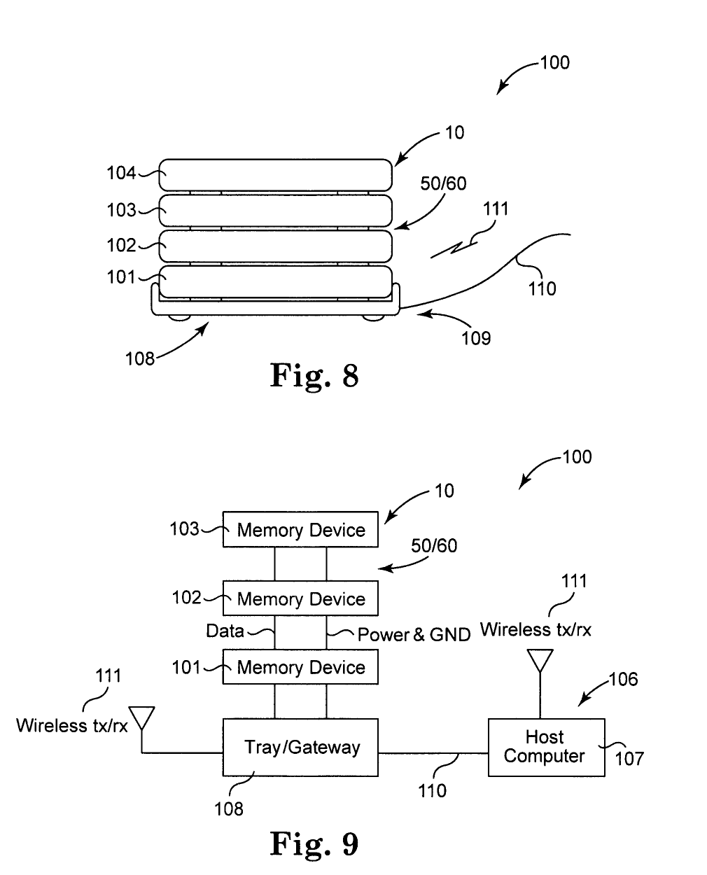

In one embodiment, as illustrated in FIGS. 8 and 9, memory system 100 includes a cradle or tray 108. In one embodiment, tray 108 supports memory devices 101, 102, 103, and/or 104, and facilitates communication of memory devices 101, 102, 103, and/or 104 with host device 106. More specifically, memory device 101 is supported by tray 108 and electrically coupled with tray 108 via electrical interface 60. As such, memory device 101 facilitates communication of memory devices 101, 102, 103, and/or 104 with host device 106. In one embodiment, tray 108 has the ability to power the first memory device resting on top of it and a number of memory devices stacked on top of the first one.

In one embodiment, tray 108 includes a host interface 109 similar to host interface 70 such that communication between memory devices 101, 102, 103, and/or 104 and host device 106 is provided via tray 108 and host interface 109 through memory device 101. As such, host interface 109 of tray 108 becomes a host interface for memory devices 101, 102, 103, and/or 104. In this way, tray 108 acts as a gateway for the stacked memory devices by allowing host device 106 to communicate with the multiple memory devices through one host interface. In one embodiment, communication between tray 108 and host device 106 includes a wired connection 110, and in another embodiment, communication between tray 108 and host device 106 includes a wireless connection 111.

With memory system 100, electrical interfaces of the memory devices provide power and data signal propagation from tray 108 or memory device 101 to the other memory devices for communication and data transfer. As such, with memory system 100, multiple memory devices 101, 102, 103, and/or 104 can be coupled to one another, and presented to host device 106 as a single virtual memory device. In this way, memory devices 101, 102, 103, and/or 104 may expand an amount of storage capacity available to host device 106 without requiring a user to purchase a new, higher capacity memory device.

In one embodiment, when memory devices 102, 103, and/or 104 are electrically connected to memory device 101, which is operative communicated with host device 106, a controller included in memory device 101 acts as a master controller and a controller included in memory devices 102, 103, and/or 104 acts as a servant controller (sometimes referred to as a slave controller). As such, the controller of memory device 101 provides read/write data access and/or power to a memory within memory device 101, as well as read/write data access and/or power to a memory within memory devices 102, 103, and/or 104. In one embodiment, the master controller virtualizes the memory of memory device 101 and memory devices 102, 103, and/or 104 to be presented to host device 106 as a single, larger capacity memory.

In one embodiment, memory devices of memory system 101 are “hot stackable” in that a memory device can be added to the stack when the system is active and communicating with host device 106. Likewise, a memory device can be removed from the stack when the system is active and communicating with host device 106.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory device, comprising:
a housing;
a memory within the housing; and
a first electrical interface accessible on a top surface of the housing and a second electrical interface accessible on a bottom surface of the housing,
wherein at least one of the first electrical interface and the second electrical interface is configured to establish electrical connection of the memory device with an electrical interface of another memory device when the memory device and the another memory device are in a stacked configuration.

2. The memory device of claim 1, further comprising:
a host connection configured to facilitate operative communication between the memory device and a host device.

3. The memory device of claim 2, wherein operative communication between the another memory device and the host device is provided via the host connection through the memory device.

4. The memory device of claim 2, wherein the host connection comprises a tray configured to support the memory device and facilitate operative communication between the memory device and the host device.

5. The memory device of claim 2, wherein the host connection comprises one of a wired connection and a wireless connection.

6. The memory device of claim 2, wherein the host device comprises a host computer.

7. The memory device of claim 1, wherein the first electrical interface and the second electrical interface of the memory device each include electrical contacts corresponding to a data signal and a ground signal.

8. The memory device of claim 7, wherein the first electrical interface and the second electrical interface of the memory device each further include electrical contacts corresponding to a power signal.

9. The memory device of claim 1, further comprising:
a stacking feature provided on the top surface and the bottom surface of the housing of the memory device, wherein the stacking feature is configured to facilitate the stacked configuration of the memory device and the another memory device.

10. The memory device of claim 9, wherein the stacking feature includes the first electrical interface provided on the top surface and the second electrical interface provided on the bottom surface of the housing of the memory device.

11. The memory device of claim 9, wherein the stacking feature comprises complementary features provided on the top surface and the bottom surface of the housing of the memory device.

12. The memory device of claim 9, wherein the stacking feature comprises magnets of opposite polarity provided on the top surface and the bottom surface of the housing of the memory device.

13. A memory device, comprising:
a housing;
a memory within the housing; and
means provided on a top surface of the housing and a bottom surface of the housing for establishing electrical connection between the memory device and another memory device when the memory device and the another memory device are in a stacked configuration.

14. The memory device of claim 13, further comprising:
means for facilitating operative communication between the memory device and a host device,
wherein operative communication between the another memory device and the host device is provided through the memory device.

15. The memory device of claim 14, wherein the means for facilitating operative communication facilitates one of wired communication and wireless communication.

16. The memory device of claim 13, wherein the means for establishing electrical connection between the memory device and the another memory device provides for communication of a data signal and a ground signal between the memory device and the another memory device.

17. The memory device of claim 16, wherein the means for establishing electrical connection between the memory device and the another memory device further provides for communication of a power signal between the memory device and the another memory device.

18. The memory device of claim 13, further comprising:
means for facilitating a stacked configuration of the memory device with the another memory device,
wherein the means for facilitating the stacked configuration is formed in part by the means for establishing electrical connection between the memory device and the another memory device.

19. A memory system, comprising:
a first memory device including a first housing, a first memory within the first housing, and a first electrical interface provided on one of a top surface and a bottom surface of the first housing; and
a second memory device including a second housing, a second memory within the second housing, and a second electrical interface provided on one of a top surface and a bottom surface of the second housing opposite the one of the top surface and the bottom surface of the first housing,
wherein the first electrical interface of the first memory device and the second electrical interface of the second memory device are configured to establish electrical connection between the first memory device and the second memory device when the first memory device and the second memory device are in a stacked configuration.

20. The memory system of claim 19, further comprising:
a host connection configured to facilitate operative communication between the first memory device and a host device.

21. The memory system of claim 20, wherein operative communication between the second memory device and the host device is provided via the host connection through the first memory device.

22. The memory system of claim 20, wherein the host connection comprises a tray configured to support the first memory device and facilitate operative communication between the first memory device and the host device.

23. The memory system of claim 20, wherein the host connection comprises one of a wired connection and a wireless connection.

24. The memory system of claim 20, wherein the host device comprises a host computer.

25. The memory system of claim 19, wherein the first electrical interface of the first memory device and the second electrical interface of the second memory device each include electrical contacts corresponding to a data signal and a ground signal.

26. The memory system of claim 25, wherein the first electrical interface of the first memory device and the second electrical interface of the second memory device each further include electrical contacts corresponding to a power signal.

27. The memory system of claim 19, further comprising:
a stacking feature provided on the top surface and the bottom surface of each of the first housing of the first memory device and the second housing of the second memory device, wherein the stacking feature facilitates the stacked configuration of the first memory device and the second memory device.

28. The memory system of claim 27, wherein the stacking feature includes the first electrical interface of the first memory device and the second electrical interface of the second memory device.

29. The memory system of claim 27, wherein the stacking feature comprises complementary features provided on the top surface and the bottom surface of each of the first housing of the first memory device and the second housing of the second memory device.

30. The memory system of the claim 27, wherein the stacking feature comprises magnets of opposite polarity provided on the top surface and the bottom surface of each of the first housing of the first memory device and the second housing of the second memory device.
